(19) United States
(12) Patent Application Publication
(10) Pub. No.: US 2013/0081689 A1
(43) Pub. Date: Apr. 4, 2013

(54) SOLAR CELL PACKAGE STRUCTURE WITH CIRCUIT DESIGN

(71) Applicants: Chj-Don TENG, Taipei City (TW); Kuang-Feng CHUNG, Taipei City (TW)

(72) Inventors: Chj-Don TENG, Taipei City (TW); Kuang-Feng CHUNG, Taipei City (TW)

(21) Appl. No.: 13/346,489

(22) Filed: Jan. 9, 2012

(30) Foreign Application Priority Data
Sep. 30, 2011 (TW) 100135495

(51) Int. Cl. H01L 31/0224

(52) U.S. Cl. 136/256

(57) ABSTRACT

A solar cell package structure with a circuit design includes a first conductive substrate, a second conductive substrate, a first conductive wire and a second conductive wire. The second conductive substrate is disposed opposite to the first conductive substrate. The first conductive wire is electrically connected to the first conductive substrate through a first conductive via. The second conductive wire is electrically connected to the second conductive substrate through a second conductive via.

### CROSS REFERENCE TO RELATED APPLICATIONS

This Non-provisional application claims priority under 35 U.S.C. §119(a) on Patent Application No(s). 100135495 filed in Taiwan, Republic of China on Sep. 30, 2011, the entire contents of which are hereby incorporated by reference.

### BACKGROUND OF THE INVENTION

1. Field of Invention

The present invention relates to a cell package structure and, in particular, to a solar cell package structure with a circuit design.

2. Related Art

Solar energy usually does not cause the environmental pollution and is easily to be retrieved, so that it has become one of the substituted energy sources. In general, the solar cell, which is a photoelectric conversion element, is used to absorb the solar light and convert the solar energy into electricity.

The common solar cells include silicon-based solar cells, compound semiconductor solar cells, organic solar cells, and dye sensitized solar cells (DSSC). Except for the material of the solar cell, the reliability of the package structure of the solar cell is also a very important factor for affecting the photoelectric conversion efficiency. If the package structure of the solar cell is not sealed airtightly, moisture and dusts may enter the package structure, thereby decreasing the performance and lifetime of the solar cell. Besides, the package structure of the DSSC usually contains electrolyte. If the package structure is not reliable, the electrolyte therein may leak out so as to damage the solar cell and decrease the production yield.

FIG. 1 is a schematic diagram showing a conventional DSSC package structure 1, which includes two conductive substrates 101 and 102. A dye layer 103 is disposed on the conductive substrate 101, and a catalyst layer 104 is disposed on the conductive substrate 102. Moreover, a conductive layer 105 is disposed on the conductive substrate 101, and another conductive layer 106 is disposed on the conductive substrate 102. The DSSC package structure 1 further includes a sealant 107 connected between the substrates 101 and 102, so that the sealant 107 and the substrates 101 and 102 can form a sealed structure.

The sealant 107 further covers parts of the conductive layers 105 and 106. An electrolyte 108 is disposed between the sealant 107 and the conductive substrates 101 and 102. In order to output the electrical signals, the DSSC package structure 1 further includes two conductive wires 109 and 110, which connect to the conductive layers 105 and 106, respectively.

In the conventional DSSC package structure 1, the sealant 107 only partially covers the conductive wires 109 and 110, so that the structural strength of the sealant 107 is weakened, and the overflow of the glue may occur. After a long term usage, the DSSC package structure 1 may lose its sealing degree due to the crevice appeared at the connection portion between the sealant 107 and the conductive wires 109 and 110. Moreover, if the sealant 107 degrades after irradiated by the solar light for a long term, the sealing degree of the DSSC package structure 1 becomes worse. These factors can sufficiently decrease the reliability and lifetime of the DSSC package structure 1.

Therefore, it is an important subject of the present invention to provide a solar cell package structure with circuit design that can overcome the above-mentioned problems, thereby increasing the reliability and lifetime of the product.

### SUMMARY OF THE INVENTION

In view of the foregoing subject, an object of the present invention is to provide a solar cell package structure with circuit design that can increase the reliability and lifetime of the product.

To achieve the above object, the present invention discloses a solar cell package structure with circuit design including a first conductive substrate, a second conductive substrate, a first conductive wire and a second conductive wire. The second conductive substrate is disposed opposite to the first conductive substrate. The first conductive wire is electrically connected to the first conductive substrate through a first conductive via. The second conductive wire is electrically connected to the second conductive substrate through a second conductive via.

In one embodiment, the first conductive via and the second conductive via are both disposed on the first conductive substrate or the second conductive substrate.

In one embodiment, the first conductive via is disposed on the first conductive substrate, and the second conductive via is disposed on the second conductive substrate.

In one embodiment, the first conductive substrate or the second conductive substrate comprises a transparent substrate.

In one embodiment, the solar cell package structure further comprises a sealant connecting the first conductive substrate and the second conductive substrate. The sealant, the first conductive substrate and the second conductive substrate form a sealed space.

In one embodiment, the solar cell package structure is applied to a silicon-based solar cell, a compound semiconductor solar cell, an organic solar cell, or a dye sensitized solar cell.

In one embodiment, the solar cell package structure further comprises a first conductive layer disposed on the first conductive substrate. The first conductive via is electrically connected to the first conductive substrate through the first conductive layer.

In one embodiment, the solar cell package structure further comprises a second conductive layer disposed on the second conductive substrate. The second conductive via is electrically connected to the second conductive substrate through the second conductive layer.

In one embodiment, the first or second conductive wire is a printed wire or a solid wire.

As mentioned above, the solar cell package structure of the present invention configures the first and second conductive vias for outputting the signals from the first and second conductive substrates. The first and second conductive vias can be disposed on a single substrate or different substrates. Therefore, the solar cell package structure of the present invention does not configure the conductive wires passing through the sealant for outputting the electricity, so that the structural strength of the sealant can be increased, thereby improving the reliability and lifetime of the product.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing a conventional dye sensitized solar cell package structure;

FIG. 2 is a cross-section view of a solar cell package structure according to a first embodiment of the present invention; and

FIG. 3 is a perspective view of a solar cell package structure according to a second embodiment of the present invention.

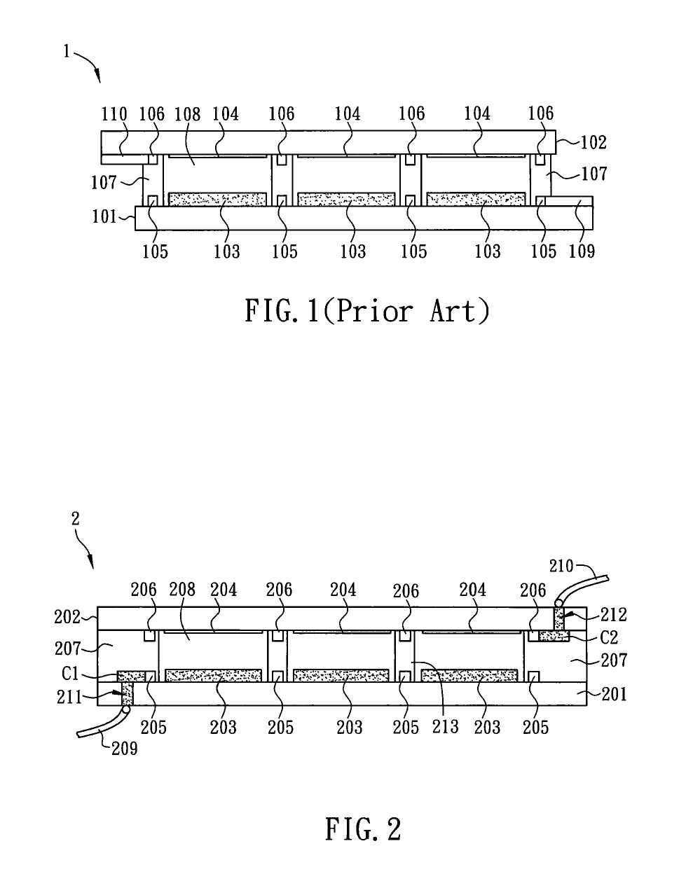

### DETAILED DESCRIPTION OF THE INVENTION

The present invention will be apparent from the following detailed description, which proceeds with reference to the accompanying drawings, wherein the same references relate to the same elements.

FIG. 2 is a cross-section view of a solar cell package structure 2 with circuit design according to a first embodiment of the present invention. The solar cell package structure 2 can be, for example but not limited to, applied to a silicon-based solar cell, a compound semiconductor solar cell, an organic solar cell, or a dye sensitized solar cell. In this embodiment, the solar cell package structure 2 is the package structure of a dye sensitized solar cell.

The solar cell package structure 2 includes a first conductive substrate 201, a second conductive substrate 202, a first conductive wire 209, a second conductive wire 210, a first conductive via 211, and a second conductive via 212. The first conductive substrate 201 and the second conductive substrate 202 are disposed opposite to each other. The first conductive via 211 is disposed on the first conductive substrate 201, and the second conductive via 212 is disposed on the second conductive substrate 202. The first conductive via 211 and the second conductive via 212 are located at opposite two sides of the solar cell package structure 2. The first conductive wire 209 is electrically connected to the first conductive substrate 201 through the first conductive via 211. The second conductive wire 210 is electrically connected to the second conductive substrate 202 through the second conductive via 212.

The material of the first conductive substrate 201 and the second conductive substrate 202 is, for example but not limited to, a silicon substrate, a ceramic substrate, a metal substrate, a glass substrate, or a plastic substrate. In this embodiment, the solar light enters through the first conductive substrate 201, so that the substrate of the first conductive substrate 201 is usually light permeable. Besides, the substrate of the second conductive substrate 202 can be opaque or light permeable. Each of the first conductive substrate 201 and the second conductive substrate 202 includes a conductive layer, which is opaque or light permeable. The material of the light-permeable conductive layer is, for example but not limited to, transparent conductive oxides such as indium tin oxide (ITO), tin oxide, or zinc oxide. Otherwise, the material of the light-permeable conductive layer can be tin dioxide doped with fluorine (Sn:F). The substrate containing the conductive layer made of tin dioxide doped with fluorine is also called as an FTO substrate.

The first conductive wire 209 or the second conductive wire 210 can be a printed wire or a solid wire. In this embodiment, the first conductive wire 209 is a solid wire. Besides, the first conductive via 211 and the second conductive via 212 contain conductive materials (e.g. by electroplating) or filled with conductive solders or plugs, which are welded to electrically connected the first conductive via 211 and the second conductive via 212 to the first conductive wire 209 or the second conductive wire 210.

In this embodiment, the solar cell package structure 2 may further include a dye layer 203 disposed on the first conductive substrate 201. A dye absorbing layer (e.g. titan dioxide) is coated on the first conductive substrate 201 in advance, and then the dye is disposed thereon so that the titan dioxide can absorb the dye so as to form the dye layer 203. The dye layer 203 can absorb light and then generate electrons, which are transmitted to the conductive layers of the conductive substrates 201 and 202. In this case, the dye contained in the dye layer 203 may include metal-complex pigments containing ruthenium, or organic pigment containing methyl or phthalocyanine.

In addition, the solar cell package structure 2 may further include a first conductive layer 205 disposed on the first conductive substrate 201. The first conductive via 211 is electrically connected with the first conductive substrate 201 through the first conductive layer 205. A part of the first conductive layer 205 is directly connected with the first conductive via 211, while another part thereof configures a frame portion around the dye layer 203. The first conductive layer 205 can be formed by printing, coating or dispensing. The configuration of the first conductive layer 205 can facilitate the transmission of electrons. In practice, the electrons generated by the dye layer 203 is transmitted to the conductive layer of the first conductive substrate 201, and then transmitted to the first conductive layer 205. In this embodiment, the first conductive layer 205 is, for example, made of silver paste or other conductive paste such as aluminum paste or copper paste. To be noted, a glass paste can be provided on the part of the first conductive layer 205 for configuring the frame portion so as to achieve the desired insulation protection. The material of the glass paste is, for example, bismuth oxide, which is used for reducing the oxidation of the frame portion of the first conductive layer 205 and providing the desired insulation. Besides, a collector portion C1, which is long-shaped for example, is usually provided at the periphery of the first conductive layer 205 for collecting the electrons generated by the solar cell package structure 2. In addition, the collector portion C1 can be used as the positive or negative electrode of the cell for electrically connecting to a next solar cell package structure 2 or external control circuit in series or in parallel.

The solar cell package structure 2 may further include a catalyst layer 204 disposed on the second conductive substrate 202. The catalyst layer 204 usually contains platinum (Pt) or carbon (C) for catalyzing the oxidation or reduction of the electrolyte 208.

The solar cell package structure 2 may further include a second conductive layer 206 disposed on the second conductive substrate 202. The second conductive via 212 is electrically connected with the second conductive substrate 202 through the second conductive layer 206. A part of the second conductive layer 206 is directly connected with the second conductive via 212, while another part thereof configures a frame portion around the catalyst layer 204. The configuration of the second conductive layer 206 can facilitate the transmission of electrons, and the first conductive layer 205 and the second conductive layer 206 form a circuit loop. Besides, a collector portion C2, which is long-shaped for example and is substantially parallel to the collector portion C1 of the first conductive layer 205, is usually provided at the periphery of the second conductive layer 206 for collecting the electrons generated by the solar cell package structure 2. In addition, the collector portion C2 can be used as the positive or negative electrode of the cell for electrically connecting to a next solar cell package structure 2 or external control circuit in series or in parallel. In this embodiment, the second conductive layer 206 is, for example, made of silver paste or other conductive paste such as aluminum paste or copper paste. To be noted, a glass paste can be provided on the part of the second conductive layer 206 for configuring the frame portion so as to form a protection layer. The material of the glass paste is, for example, bismuth oxide, which is used for reducing the oxidation of the frame portion of the second conductive layer 206 and preventing short circuit between the first conductive layer 205 and the second conductive layer 206.

The solar cell package structure 2 may further include a sealant 207 for connecting the first conductive substrate 201 and the second conductive substrate 202. The first conductive substrate 201, the second conductive substrate 202 and the sealant 207 form an airtight sealing space. In this embodiment, the sealant 207 is made of the resin material with water-proof and thermal resisting properties, for extending the lifetime of the product.

In order to increase the connection strength between the first conductive substrate 201 and the second conductive substrate 202, a bonding glue 213 may be provided between the first conductive substrate 201 and the second conductive substrate 202. In this embodiment, the bonding glue 213 is disposed between the first conductive layer 205 and the second conductive layer 206 for bonding the first conductive substrate 201 and the second conductive substrate 202. The sealant 207 and the bonding glue 213 may be made of the same material such as hot-melt glue, UV glue, or epoxy.

Moreover, the solar cell package structure 2 may further include an electrolyte 208 filled within the sealing space. The molecules of the dye layer 203 can absorb the solar light and excited so as to inject electrons into the first conductive substrate 201 or the first conductive layer 205. At the same time, the molecules of the dye layer 203 transform into an oxide state. Then, the oxide dye molecules can receive electrons from the electrolyte 208 and thus return to the ground state, thereby recycling the dye molecules. After providing the electrons, the electrolyte 208 is diffused toward the second conductive substrate 202 or the second conductive layer 206 for retrieving electrons (reduction reaction). This is a complete photoelectric chemical reaction cycle.

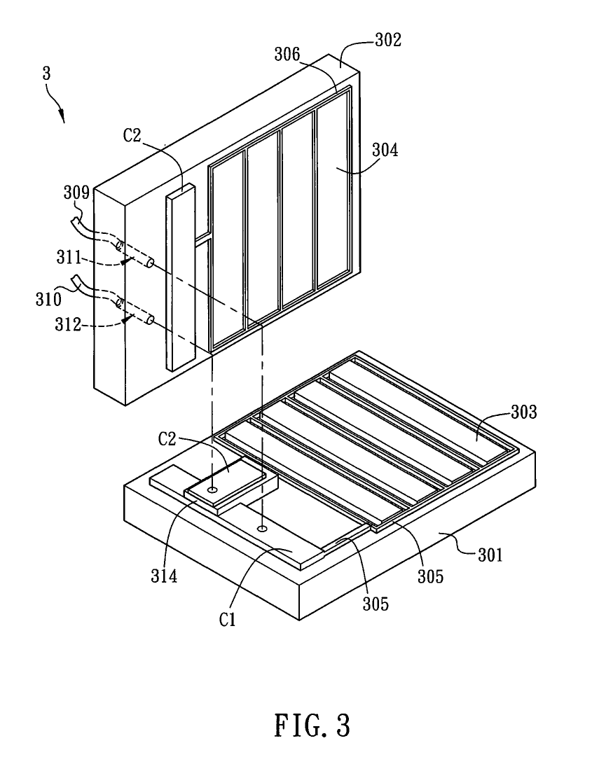

FIG. 3 is a perspective view of a solar cell package structure 3 with circuit design according to a second embodiment of the present invention.

With reference to FIG. 3, the solar cell package structure 3 includes a first conductive substrate 301, a second conductive substrate 302, a first conductive wire 309, a second conductive wire 310, a sealant (not shown), an electrolyte (not shown), a first conductive via 311, a second conductive via 312, a first conductive layer 305, a second conductive layer 306, a dye layer 303, and a catalyst layer 304. The first conductive substrate 301, the second conductive substrate 302, the first conductive wire 309, the second conductive wire 310, the sealant, the electrolyte, the dye layer 303, and the catalyst layer 304 are similar to the same elements in the first embodiment, so the detailed descriptions thereof will be omitted.

Compared with the first embodiment, the first conductive via 311 and the second conductive via 312 of the solar cell package structure 3 in the second embodiment are both disposed on the same substrate and located on the same side. In this case, the first conductive via 311 and the second conductive via 312 are both disposed on the second conductive substrate 302, and they are apart from each other with a distance. The first conductive layer 305 is connected with the first conductive via 311, so that the first conductive wire 309 can be electrically connected with the first conductive substrate 301 through the first conductive via 311 and the first conductive layer 305 for outputting the electricity. Similarly, the second conductive layer 306 is connected with the second conductive via 312, so that the second conductive wire 310 can be electrically connected with the second conductive substrate 302 through the second conductive via 312 and the second conductive layer 306 for outputting the electricity.

In addition, the solar cell package structure 3 may further include an insulation layer 314. Since the first conductive layer 305 and the second conductive layer 306 are partially overlapped along their projection direction, the insulation layer 314 configured between the collector portion C1 of the first conductive layer 305 and the collector portion C2 of the second conductive layer 306 can insulate the first conductive layer 305 from the second conductive layer 306. To be noted, FIG. 3 shows that a part of the collector portion C2 is located on the first conductive substrate 301; in practice, however, it can also be located on the second conductive substrate 302.

In summary, the solar cell package structure of the present invention configures the first and second conductive vias for outputting the signals from the first and second conductive substrates. The first and second conductive vias can be disposed on a single substrate or different substrates. Therefore, the solar cell package structure of the present invention does not configure the conductive wires passing through the sealant for outputting the electricity, so that the structural strength of the sealant can be increased, thereby improving the reliability and lifetime of the product.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A solar cell package structure with a circuit design, comprising:
a first conductive substrate;
a second conductive substrate disposed opposite to the first conductive substrate;
a first conductive wire electrically connected to the first conductive substrate through a first conductive via; and
a second conductive wire electrically connected to the second conductive substrate through a second conductive via.

2. The solar cell package structure according to claim 1, wherein the first conductive via and the second conductive via are both disposed on the first conductive substrate or the second conductive substrate.

3. The solar cell package structure according to claim 1, wherein the first conductive via is disposed on the first conductive substrate, and the second conductive via is disposed on the second conductive substrate.

4. The solar cell package structure according to claim 1, wherein the first conductive substrate or the second conductive substrate comprises a transparent substrate.

5. The solar cell package structure according to claim 1, further comprising:
a sealant connecting the first conductive substrate and the second conductive substrate, wherein the sealant, the first conductive substrate and the second conductive substrate form a sealed space.

6. The solar cell package structure according to claim 1, wherein the solar cell package structure is applied to a silicon-based solar cell, a compound semiconductor solar cell, or an organic solar cell.

7. The solar cell package structure according to claim 1, wherein the solar cell package structure is applied to a dye sensitized solar cell.

8. The solar cell package structure according to claim 1, further comprising:
a first conductive layer disposed on the first conductive substrate, wherein the first conductive via is electrically connected to the first conductive substrate through the first conductive layer.

9. The solar cell package structure according to claim 1, further comprising:
a second conductive layer disposed on the second conductive substrate, wherein the second conductive via is electrically connected to the second conductive substrate through the second conductive layer.

10. The solar cell package structure according to claim 1, wherein the first conductive wire or the second conductive wire is a printed wire or a solid wire.
